(19) United States
(12) Patent Application Publication
(10) Pub. No.: US 2023/0005715 A1
(43) Pub. Date: Jan. 5, 2023

(54) APPARATUS AND METHOD FOR TREATING SUBSTRATE

(71) Applicant: SEMES CO., LTD., Cheonan-si (KR)

(72) Inventors: Jin Woo CHOI, Suwon-Si (KR); Jang Hee LEE, Hwaseong-si (KR); Young Hak PARK, Cheonan-si (KR); Seung Jun OH, Hwaseong-si (KR); Ahn Na SEO, Cheonan-si (KR)

(73) Assignee: SEMES CO., LTD., Cheonan-si (KR)

(21) Appl. No.: 17/851,812

(22) Filed: Jun. 28, 2022

(30) Foreign Application Priority Data
Jun. 30, 2021 (KR) 10-2021-0085983

(51) Int. Cl. H01J 37/32; H01L 21/67

(52) U.S. Cl. CPC H01J 37/3244; H01J 37/32724; H01J 37/32844; H01L 21/67103; H01J 37/32477; H01J 37/32192

(57) ABSTRACT

The inventive concept provides a substrate treating apparatus. The substrate treating apparatus includes a process chamber provided with a reaction space and having at least one insulation member exposed to the reaction space; a substrate support member for supporting a substate at the reaction space; a gas supply member for selectively supplying a passivation gas or a process gas to the reaction space; a plasma source for exciting the passivation gas or the process gas to a plasma; and a controller for controlling the gas supply member and the plasma source, and wherein the controller controls the gas supply member and the plasma source so the passivation gas is supplied to the reaction space and a supplied passivation gas is excited to the plasma, in a state at which the substrate is not taken into the reaction space.

### CROSS-REFERENCE TO RELATED APPLICATIONS

A claim for priority under 35 U.S.C. § 119 is made to Korean Patent Application No. 10-2021-0085983 filed on Jun. 30, 2021, in the Korean Intellectual Property Office, the entire contents of which are hereby incorporated by reference.

### BACKGROUND

Embodiments of the inventive concept described herein relate to a substrate treating apparatus and a substrate treating method.

As semiconductor devices became highly integrated, a size of an active region also decreased. As a result, a channel length of an MOS transistor formed in the active region has also decreased. When the channel length of the MOS transistor decreases, an operation performance of the transistor decreases due to a short channel effect. Accordingly, various studies have been conducted to maximize the performance of a device while reducing the size of the devices formed on the substrate.

Among them, a representative example is a fin-FET device having a fin structure. Such a fin-FET device may be formed by etching a substrate such as a wafer including a silicon (Si). In this case, a roughness of a substrate surface generated during an etching process may cause a deterioration in performance of the transistor. Accordingly, in general, a damage and the roughness of the substrate surface are improved through an annealing treatment that applying radicals to the substrate surface. As a method for healing such damage, an annealing method using a hydrogen plasma has been proposed. This method is known to heal such damage by injecting a hydrogen into the process chamber and forming a plasma, making silicon atoms on the surface of the channel movable by radical hydrogen. However, in order to actually apply this to plasma treating apparatuses, several problems such as particle generation need to be solved.

In the related art, in order to solve the above-described particle generation problem, a step of nitrogen passivation on surfaces of insulation members at in inner circumference of a reaction chamber was performed as a pre-step of a hydrogen plasma annealing treatment. However, a conventional passivation method may resolve the problem of the particle generation within the chamber, but there is a problem of changing a nitrogen concentration in the substrate during the hydrogen plasma annealing treatment. Specifically, FIG. 1(A) and FIG. 1(B) illustrate a substrate treating apparatus for performing a substrate treating method according to the related art. FIG. 1(A) illustrates a process chamber after a passivation step, and FIG. 1(B) illustrates a process chamber after a hydrogen plasma annealing. Referring to FIG. 1(A) and FIG. 1(B), in a conventional passivation step, a passivation is performed using a strong plasma having a high nitrogen concentration. Accordingly, the nitrogen concentration remaining within a chamber or at an insulation member after the passivation step is high, and thus a nitrogen concentration deposited on the substrate in a hydrogen plasma annealing step is also high.

In addition, as the nitrogen concentration in the substrate is changed, there is a problem that a growth of an oxide film is not constant in a subsequent process after an annealing.

### SUMMARY

Embodiments of the inventive concept provide a substrate treating apparatus and a substrate treating method for efficiently treating a substrate.

Embodiments of the inventive concept provide a substrate treating apparatus and a substrate treating method for effectively performing a surface treatment of a substrate.

Embodiments of the inventive concept provide a substrate treating apparatus and a substrate treating method which protects insulation members provided at an apparatus, and minimizes a particle contamination of a substrate.

Embodiments of the inventive concept provide a substrate treating apparatus and a substrate treating method for constantly maintaining a nitrogen concentration in a substrate.

Embodiments of the inventive concept provide a substrate treating apparatus and a substrate treating method for growing a film having a predetermined thickness.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a process chamber provided with a reaction space and having at least one insulation member exposed to the reaction space; a substrate support member for supporting a substate at the reaction space; a gas supply member for selectively supplying a passivation gas or a process gas to the reaction space; a plasma source for exciting the passivation gas or the process gas to a plasma; and a controller for controlling the gas supply member and the plasma source, and wherein the controller controls the gas supply member and the plasma source so the passivation gas is supplied to the reaction space and a supplied passivation gas is excited to the plasma, in a state at which the substrate is not taken into the reaction space.

In an embodiment, an exhaust line for exhausting the reaction space and a depressurizing member installed at the exhaust line is provided at the process chamber, and wherein the controller controls the depressurizing member so a pressure of the reaction space becomes a pressure of 150 mTorr to 1000 mTorr.

In an embodiment, the controller controls the gas supply member so the passivation gas has is supplied for 10 seconds to 60 seconds at 10 sccm to 1000 sccm.

In an embodiment, an insulation member is formed of at least one of a material among a quartz, an Al203, an AlN, and/or a Y203.

In an embodiment, the passivation gas includes a nitrogen gas.

In an embodiment, the passivation gas further includes a hydrogen gas or an inert gas.

In an embodiment, the hydrogen gas or the inert gas is supplied at a flow rate of 10 sccm to 1000 sccm for 10 seconds to 60 seconds.

In an embodiment, a plasma excited from the passivation gas reacts with an insulation member to passivate a surface of the insulation member.

In an embodiment, the controller controls the substrate treating apparatus so the substrate is taken into the reaction space after a surface of an insulation member is passivated,

In an embodiment, the gas supply member includes: a first gas supply member for supplying the process gas to the reaction space; and a second gas supply member for supplying the passivation gas to the reaction space, and wherein the controller controls the second gas supply member so the process gas is supplied to the reaction space after the substrate is taken into the reaction space.

In an embodiment, the process gas includes a hydrogen.

In an embodiment, the controller controls the gas supply member and the plasma source so a hydrogen plasma annealing treatment is performed on a substate taken into the reaction space.

The inventive concept provides a substrate treating method. The substrate treating method includes passivating an insulation member within a reaction space; and hydrogen plasma annealing treating a substrate, and wherein the passivating the insulation member within the reaction space includes: providing a reaction chamber at which a substrate has not been introduced to the reaction space; supplying a passivation gas into the reaction space; and exciting the passivation gas to a plasma.

In an embodiment, a pressure of the reaction space at the passivating the insulation member within the reaction space is a pressure of 150 mTorr to 1000 mTorr.

In an embodiment, the passivation gas includes a nitrogen-based gas, and the nitrogen-based gas is supplied at a flow rate of 10 sccm to 1000 sccm for 10 seconds to 60 seconds.

In an embodiment, the passivation gas further includes a hydrogen gas or an inert has, and the hydrogen gas or the inert gas is supplied at a flow rate of 10 sccm to 1000 sccm together with the nitrogen-based gas.

In an embodiment, the hydrogen plasma annealing treating the substrate is performed after the passivating the insulation member within the reaction space.

In an embodiment, the hydrogen plasma annealing treating the substrate includes: taking in the substrate to the reaction space; supplying a process gas within the reaction space; and exciting the process gas to the plasma.

In an embodiment, the hydrogen plasma annealing treating the substrate includes: taking in the substrate to the reaction space; supplying a process gas within the reaction space; and exciting the process gas to the plasma.

In an embodiment, the process gas is a hydrogen gas or an inert gas.

The inventive concept provides a substrate treating apparatus. The substrate treating apparatus includes a process chamber provided with a reaction space and having at least one insulation member exposed to the reaction space; a substrate support member for supporting a substate at the reaction space; a gas supply member for selectively supplying a passivation gas including a nitrogen gas or a process gas including a hydrogen to the reaction space; a plasma source for exciting a gas to a plasma; and a controller, and wherein the controller controls the gas supply member to sequentially perform a first step of passivation treating the insulation member by supplying the passivation gas to the reaction space before the substrate is taken into the reaction space, and a second step of hydrogen plasma annealing treating the substrate by supplying the process gas to the reaction space after the substrate is taken to the reaction space, and wherein the controller controls the gas supply member so the passivation gas is supplied at a flow rate of 10 sccm to 1000 sccm for 10 seconds to 60 seconds, at an atmosphere controlled so which a pressure of the reaction space is controlled to be a pressure of 150 mTorr to 1000 mTorr.

According to an embodiment of the inventive concept, a substrate treating apparatus and a substrate treating method for efficiently treating a substate may be provided.

According to an embodiment of the inventive concept, a substrate treating apparatus and a substrate treating method for effectively performing a surface treatment of a substrate may be provided.

According to an embodiment of the inventive concept, insulation members provided at an apparatus may be protected and a particle contamination of a substrate may be minimized.

According to an embodiment of the inventive concept, a nitrogen concentration may be constantly maintained.

According to an embodiment of the inventive concept, a film having a predetermined thickness may be grown.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1(A) and FIG. 1(B) illustrate a substrate treating apparatus for performing a substrate treating method according to the related art.

FIG. 2 illustrates a substrate treating apparatus according to an embodiment of the inventive concept.

FIG. 3 is a flowchart illustrating a substrate treating method according to an embodiment of the inventive concept.

FIG. 4 is a flowchart illustrating the substrate treating method according to step S100 of FIG. 3.

FIG. 5 illustrates an image of the substrate treating apparatus performing step S100 of FIG. 3.

FIG. 6 schematically illustrates a surface of insulation members being changed by a nitrogen passivation through step S100 of FIG. 3.

FIG. 7 is a flowchart illustrating the substrate treating method according to step S200 of FIG. 3.

FIG. 8 illustrates an image of the substrate treating apparatus performing step S200 of FIG. 3.

FIG. 9 is a graph comparing a change in a thickness of an oxide film of the substrate treating method according to an embodiment of the inventive concept and a substrate treating method according to a comparative embodiment.

FIG. 10 is a graph comparing a nitrogen concentration in a substrate of the substrate treating method according to an embodiment of the inventive concept and the substrate treating method according to the comparative embodiment.

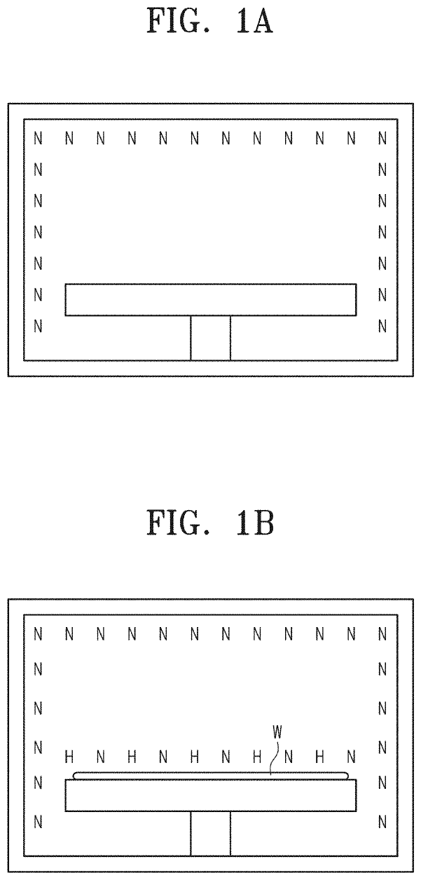

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising”, “includes”, and/or “including” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “example” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Other terms such as “between”, “adjacent”, “near” or the like should be interpreted in the same way.

Unless otherwise defined, all terms used herein, including technical or scientific terms, have the same meaning as those generally understood by those skilled in the art to which the inventive concept belongs. Terms such as those defined in commonly used dictionaries should be interpreted as consistent with the context of the relevant technology and not as ideal or excessively formal unless clearly defined in this application.

Hereinafter, embodiments of the inventive concept will be described in detail with reference to the drawings.

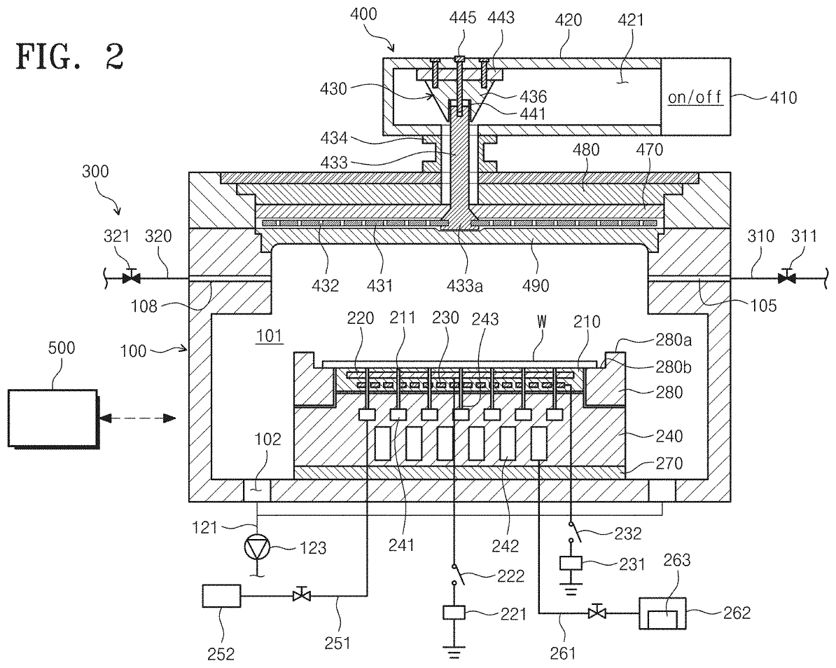

FIG. 2 illustrates a substrate treating apparatus according to an embodiment of the inventive concept.

Referring to FIG. 2, the substrate treating apparatus 10 performs a plasma processing on the substrate W. The substrate treating apparatus 10 includes a process chamber 100, a substrate support member 200, a gas supply member 300, a microwave application unit 400, and a controller 500.

The process chamber 100 may have a reaction space 101. The reaction space 101 may be a space in which the substrate W is treated. An opening (not shown) may be formed on a sidewall of the process chamber 100. The opening is provided as a passage through which the substrate W may enter and exit the process chamber 100. The opening is opened and closed by a door (not shown). An exhaust hole 102 is formed on a bottom surface of the process chamber 100. The exhaust hole 102 is connected to an exhaust line 121. The exhaust line 121 may be connected to a depressurizing member 123. The depressurizing member 123 may be a pump. A reaction by-product generated during the process and a gas remaining inside the process chamber 100 may be discharged to an outside through the exhaust line 121.

In addition, a pressure of the reaction space 101 may be maintained at a set pressure by a depressurizing provided by the depressurizing member 123 through the exhaust line 121. The pressure of the reaction space 101 may be maintained at a pressure close to a vacuum. That is, the process chamber 100 may be a vacuum chamber in which the pressure of the reaction space 101 is maintained at a pressure close to the vacuum during treating of the substrate W. For example, the controller 500 to be described later may control the depressurizing member 123 such that the pressure of the reaction space 101 becomes a pressure of 150 mTorr to 1000 mTorr (e.g., 10 mTorr or more, and 4 Torr or less).

The substrate support member 200 is located inside the process chamber 100. The substrate support member 200 supports the substrate W. The substrate support member 200 may include an electrostatic chuck ESC that sucks the substrate W using an electrostatic force.

It is described that the substrate support member 200 according to an embodiment includes the electrostatic chuck ESC. The substrate support member 200 includes a dielectric plate 210, a bottom electrode 220, a heater 230, a support plate 240, an insulating plate 270, and a focus ring 280.

The dielectric plate 210 is located at a top end of the substrate support member 200. The dielectric plate 210 is provided as a disk-shaped dielectric substance. The substrate W is disposed on a top surface of the dielectric plate 210. The top surface of the dielectric plate 210 has a radius smaller than that of the substrate W. Therefore, an edge region of the substrate W is located outside the dielectric plate 210. A first supply fluid channel 211 is formed at the dielectric plate 210. The first supply fluid channel 211 is provided to extend in a bottom direction from the top surface of the dielectric plate 210. A plurality of first supply fluid channels 211 are formed to be spaced apart from each other. The first supply fluid channel 211 is provided as a passage through which a heat transfer medium is supplied to the bottom surface of the substrate W.

The bottom electrode 220 and the heater 230 are buried within the dielectric plate 210. The bottom electrode 220 is located above the heater 230. The bottom electrode 220 is electrically connected to a bottom power source 221. The bottom power source 221 includes a DC power. A bottom power switch 222 is installed between the bottom electrode 220 and the bottom power source 221. The bottom electrode 220 may be electrically connected to the bottom power source 221 by an on/off of the bottom power switch 222. When the bottom power switch 222 is turned on, a DC current is applied to the bottom electrode 220. An electric force acts between the bottom electrode 220 and the substrate W by the current applied to the bottom electrode 220, and the substrate W is sucked to the dielectric plate 210 by the electric force.

The heater 230 may be a temperature control member that adjusts a temperature of the substrate W to a set temperature. In addition, the substrate W is maintained at the set temperature by a heat generated by the heater 230. The heater 230 includes a coil having a spiral shape. The heater 230 may be buried in the dielectric plate 210 at uniform intervals. The heater 230 may be heated by receiving a power from the heater power source 231. In addition, a heater power switch 232 may be installed between the heater 230 and the heater power source 231. The heater 230 may be electrically connected to the heater power source 231 by turning on/off the heater power switch 232. In addition, the temperature of the heater 230 may vary depending on a magnitude of power applied by the heater power source 231 to the heater 230. For example, the temperature of the heater 230 may also increase in proportion to the magnitude of power applied to the heater 230. In addition, the heater 230 may be connected to a heater sensor (not shown) that senses the temperature of the heater 230. The heater sensor may sense the temperature of the heater 230 in real time and transmit a detected real-time temperature of the heater 230 to the controller 500 to be described later. The controller 500 may vary the magnitude of power transmitted to the heater 230 based on the temperature of the heater 230 sensed by the heater sensor.

The support plate 240 is located below the dielectric plate 210. The bottom surface of the dielectric plate 210 and a top surface of the support plate 240 may be adhered by an adhesive 236. The support plate 240 may be provided in an aluminum material. The top surface of the support plate 240 may be stepped such that a central region is located higher than an edge region. The central region of the top surface of the support plate 240 has an area corresponding to the bottom surface of the dielectric plate 210 and is adhered to the bottom surface of the dielectric plate 210. A first circulation fluid channel 241, a second circulation fluid channel 242, and a second supply fluid channel 243 are formed at the support plate 240.

The first circulation fluid channel 241 is provided as a passage through which the heat transfer medium circulates. The first circulation fluid channel 241 may be formed in a spiral shape inside the support plate 240. Alternatively, the first circulation fluid channel 241 may be disposed such that ring-shaped fluid channels having different radii have the same center. Each of the first circulation fluid channels 241 may communicate with each other. The first circulation fluid channels 241 are formed at the same height.

The second circulation fluid channel 242 is provided as a passage through which a cooling fluid circulates. The second circulation fluid channel 242 may be formed in a spiral shape within the support plate 240. Alternatively, the second circulation fluid channel 242 may be disposed such that ring-shaped fluid channels having different radii have the same center. Each of the second circulation fluid channels 242 may communicate with each other. The second circulation fluid channel 242 may have a cross-sectional area greater than that of the first circulation fluid channel 241. The second circulation fluid channels 242 are formed at the same height. The second circulation fluid channel 242 may be located below the first circulation fluid channel 241.

The second supply fluid channel 243 upwardly extends from the first circulation fluid channel 241 and is provided to the top surface of the support plate 240. The second supply fluid channel 243 is provided in a number corresponding to the first supply fluid channel 211, and connects the first circulation fluid channel 241 and the first supply fluid channel 211.

The first circulation fluid channel 241 is connected to a heat transfer medium storage unit 252 through a heat transfer medium supply line 251. The heat transfer medium is stored in the heat transfer medium storage unit 252. The heat transfer medium includes an inert gas. According to an embodiment, the heat transfer medium includes a helium (He) gas. The helium gas is supplied to the first circulation fluid channel 241 through the supply line 251, and is supplied to the bottom surface of the substrate W through the second supply fluid channel 243 and the first supply fluid channel 211 sequentially. The helium gas serves as a medium through which a heat transferred from the plasma to the substrate W is transferred to the substrate support member 200. The ion particles contained in the plasma are attracted to the electric force formed in the substrate support member 200 and move to the substrate support member 200, and collide with the substrate W to perform an etching process while moving. A heat is generated at the substrate W while the ion particles collide with the substrate W. The heat generated from the substrate W is transferred to the substrate support member 200 through the helium gas supplied to the space between the bottom surface of the substrate W and the top surface of the dielectric plate 210.

Thereby, the substrate W may be maintained at a set temperature.

The second circulation fluid channel 242 is connected to a cooling fluid storage unit 262 through a cooling fluid supply line 261. The cooling fluid is stored in the cooling fluid storage unit 262. A cooler 263 may be provided within the cooling fluid storage unit 262. The cooler 263 cools the cooling fluid to a preset temperature. Alternatively, the cooler 263 may be installed on the cooling fluid supply line 261. The cooling fluid supplied to the second circulation fluid channel 242 through the cooling fluid supply line 261 circulates along the second circulation fluid channel 242 to cool the support plate 240. A cooling of the support plate 240 cools the dielectric plate 210 and the substrate W together to maintain the substrate W at a preset temperature.

The insulating plate 270 is provided below the support plate 240. The insulating plate 270 is provided in a size corresponding to that of the support plate 240. The insulating plate 270 is located between the support plate 240 and the bottom surface of the chamber 100. The insulating plate 270 is made of an insulating material, and electrically insulates the support plate 240 from the chamber 100.

The focus ring 280 is disposed in an edge region of the substrate support member 200. The focus ring 280 has a ring shape and is disposed along a circumference of the dielectric plate 210. A top surface of the focus ring 280 may be stepped such that an outer portion 280a is higher than an inner portion 280b. The inner portion 280b of the top surface of the focus ring 280 is located at a same height as the top surface of the dielectric plate 210. The inner portion 280b of the top surface of the focus ring 280 supports the edge region of the substrate W located outside the dielectric plate 210. The outer portion 280a of the focus ring 280 is provided to surround the edge region of the substrate W. The focus ring 280 expands an electric field forming region so that the substrate W is located at a center of the region in which the plasma is formed. Accordingly, the plasma is uniformly formed over the entire area of the substrate W, so that each area of the substrate W may be uniformly etched.

The gas supply member 300 supplies a gas to the reaction space 101 of the process chamber 100. The gas supply member 300 may supply the gas into the process chamber 100 through the first gas supply hole 105 and the second gas supply hole 108 formed in the sidewall of the process chamber 100. The gas supplied by the gas supply member 300 to the reaction space 101 includes a process gas and a passivation gas. The process gas may include at least one gas selected from a hydrogen, an inert gas, or combinations thereof. Examples of the inert gas may include a helium (He), a neon (Ne), an argon (Ar), a krypton (Kr), a xenon (Xe), a radon (Rn), and the like. The passivation gas may include at least one gas selected from a nitrogen-based gas, an inert gas or combinations thereof. For example, the nitrogen-based gas may include at least one gas selected from N2, an ammonia (NH3), a hydrazine (NH4), or combinations thereof. Examples of the inert gas may include a helium (He), a neon (Ne), an argon (Ar), a krypton (Kr), a xenon (Xe), a radon (Rn), and the like.

A first gas supply hole 105 is connected to the first gas supply line 310. The first gas supply line 310 is connected to a process gas supply source (not shown). An opening/closing member 311 is installed at the first gas supply line 310, and whether or not the process gas is supplied to the reaction space 101 may be controlled according to an opening/closing operation of the opening/closing member 311. The second gas supply hole 108 is connected to the second gas supply line 320. The second gas supply line 320 is connected to a passivation gas supply source (not shown). An opening/closing member 321 is installed at the second gas supply line 320, and whether or not the passivation gas is supplied to the reaction space 101 may be controlled according to an opening/closing operation of the opening/closing member 321.

The microwave application unit 400 is provided as an example of a plasma source that applies an energy to the reaction space 101 of the process chamber 100 to excite a gas in the reaction space 101 into a plasma. The microwave application unit 400 may generate the plasma by exciting a process gas and/or a passivation gas.

The plasma excited from the process gas may include hydrogen radicals. The hydrogen radicals may be applied to the substrate W to remove impurities attached to the substrate W or to improve a roughness with respect to the surface of the substrate W. The plasma excited from the passivation gas passivates the surfaces of the insulation members. The insulation members may be, for example, a dome member 490 provided as a ceiling of the reaction space 101, a sidewall liner (not shown), an exhaust baffle (not shown), etc. At least one of these components may be made of, for example, a material such as a quartz, an Al2O3, an AlN, and/or a Y2O3.

The microwave application unit 400 includes a microwave power source 410, a waveguide 420, a microwave antenna 430, a dielectric plate 470, a cooling plate 480, and a dome member 490.

The microwave power source 410 generates microwaves. The waveguide 420 is connected to the microwave power source 410 and provides a passage through which a microwave generated from the microwave power source 410 are transferred.

The microwave antenna 430 is located inside a front end of the waveguide 420. The microwave antenna 430 applies the microwave transferred through the waveguide 420 to an inside of the process chamber 100. For example, the microwave antenna 430 may receive a power applied by the microwave power source 410 and apply the microwave to the reaction space 101. In an embodiment, the microwave may have a preset power at a frequency of 2.45 GHz. The power applied to the microwave power source 410 may range from about 1000 W to about 3500 W.

The microwave antenna 430 includes an antenna plate 431, an antenna rod 433, an external conductor 434, a microwave adapter 436, a connector 441, a cooling plate 443, and an antenna height adjuster 445.

The antenna plate 431 is provided as a thin disk, and a plurality of slot holes 432 are formed. The slot holes 432 provide a passage through which microwaves pass through the slot holes 432. The slot holes 432 may be provided in various shapes. The slot holes 432 may be provided in a shape such as ‘×’, ‘+’, ‘−’, or the like. The slot holes 432 may be arranged to define a plurality of ring shapes. The rings have a same center and have radii of different sizes.

The antenna rod 433 is provided as a cylindrical rod. The antenna rod 433 is disposed with its lengthwise direction in an up/down. The antenna rod 433 is located above the antenna plate 431, and a bottom end portion thereof is inserted and fixed to a center of the antenna plate 431. The antenna rod 433 propagates the microwave to the antenna plate 431.

The external conductor 434 is located below a front end of the waveguide 420. A space connected to an inner space of the waveguide 420 is formed within the outer conductor 434 in the up/down direction. A partial region of the antenna rod 433 is located within the external conductor 434.

The microwave adapter 436 is located within the front end portion of the waveguide 420. The microwave adapter 436 has a cone shape in which a top end has a larger radius than a bottom end. An accommodation space with an open bottom surface is formed at the bottom end of the microwave adapter 436.

The connector 441 is located at the accommodation space. The connector 441 is provided in a ring shape. An outer face of the connector 441 has a radius corresponding to an inner face of the accommodation space. The outer face of the connector 441 is fixedly located by being in contact with the inner face of the accommodation space. The connector 441 may be formed of a conductive material. A top end of the antenna rod 433 is located within the accommodation space and is fitted into an inner region of the connector 441. The top end of the antenna rod 433 is press fitted into the connector 441, and is electrically connected to the microwave adapter 436 through the connector 441.

The cooling plate 443 is coupled to a top end of the microwave adapter 436. The cooling plate 443 may be provided as a plate having a larger radius than the top end portion of the microwave adapter 436. The cooling plate 443 may be made of a material having a better thermal conductivity than the microwave adapter 436. The cooling plate 443 may be made of a copper (Cu) or an aluminum (Al). The cooling plate 443 promotes a cooling of the microwave adapter 436, thereby preventing thermal deformation of the microwave adapter 436.

The antenna height adjustment unit 445 connects the microwave adapter 436 and the antenna rod 433. In addition, the antenna height adjustment unit 445 moves the antenna rod 433 so that a relative height of the antenna plate 431 with respect to the microwave adapter 436 is changed. The antenna height adjustments unit 445 includes a bolt. The bolt 445 is inserted into the microwave adapter 436 in the up/down direction from a top to a bottom of the microwave adapter 436, and a bottom end is located in the accommodation space. The bolt 445 is inserted into a central region of the microwave adapter 436. The bottom end of the bolt 445 is inserted into the top end of the antenna rod 433. A screw groove into which the bottom end of the bolt 445 is inserted and fastened is formed at a preset depth in a top end portion of the antenna rod 433. The antenna rod 433 is moved in the up/down direction according to a rotation of the bolt 445. For example, when the bolt 445 is rotated clockwise, the antenna rod 433 may rise, and when the bolt 445 is rotated counterclockwise, the antenna rod 433 may fall. The antenna plate 431 may be moved in the up/down direction together with a movement of the antenna rod 433.

The dielectric plate 470 is located above the antenna plate 431. The dielectric plate 470 is provided as a dielectric material such as an alumina and a quartz. The microwave propagated in the up/down direction from the microwave antenna 430 propagate\ in a radial direction of the dielectric plate 470. The microwave propagated to the dielectric plate 470 is compressed and resonated. The resonant microwave is transmitted to the slot holes 432 of the antenna plate 431.

The cooling plate 480 is provided above the dielectric plate 470. The cooling plate 480 cools the dielectric plate 470. The cooling plate 480 may be formed of an aluminum material. The cooling plate 480 may cool the dielectric plate 470 by flowing a cooling fluid through a cooling fluid channel (not shown) formed therein. Cooling methods include a water-cooling method and an air-cooling method.

The dome member 490 is provided below the antenna plate 431. The dome member 490 is provided as a dielectric material such as an alumina or a quartz. The microwave passing through the slot holes 432 of the antenna plate 431 are radiated into the process chamber 100 through the dome member 490. The process gas supplied into the process chamber 100 by the electric field of the emitted microwave is excited in a plasma state. A top surface of the dome member 490 may be spaced apart from a bottom surface of the antenna plate 431 by a preset interval.

The antenna height adjustment unit 445 may move the antenna rod 433 in the up/down direction so that the relative height of the antenna plate 431 with respect to the microwave adapter 436 is changed. The antenna height adjustment unit 445 may move the antenna rod 433 in the up/down direction to maintain the antenna plate 431 and the dome member 490 at appropriate intervals.

The controller 500 may control the substrate treating apparatus 10. The controller 500 may control at least one of the depressurizing member 123, the substrate support member 200, the gas supply member 300, and/or the microwave application unit 400 of the substrate treating apparatus 10 to perform a substrate treating method described below. In addition, the controller 500 may be provided with: a process controller made of a microprocessor (computer) that controls the substrate treating apparatus 10, a keyboard in which an operator operates a command input operation or the like to manage the substrate treating apparatus, a user interface made of a display or another object that visualizes and displays the operation of the substrate treating apparatus, a control program for executing treatment in the substrate treating apparatus under a control of the process controller, a program for executing a treatment in each component according to various data and treating conditions, and a storage unit storing a treating recipe. In addition, the user interface and the storage unit may be connected to the process controller. The treating recipe may be stored in a storage medium of the storage unit, the storage medium may be a hard disk, a portable disk such as a CD-ROM, a DVD, or a semiconductor memory such as a flash memory.

The controller 500 may maintain the temperature of the substrate W at a set temperature by adjusting the magnitude of power transferred by the heater power source 231 to the heater 230. For example, the controller 500 may recognize the temperature of the heater 230 detected by the heater sensor in real time. In addition, parameters in which the temperature of the substrate W changes according to the temperature of the heater 230, which is an experimental data previously performed, may be input to the controller 500. The controller 500 may control a supply of the process gas and the passivation gas. The controller 500 may control the depressurizing member 123 to adjust the pressure of the reaction space 101.

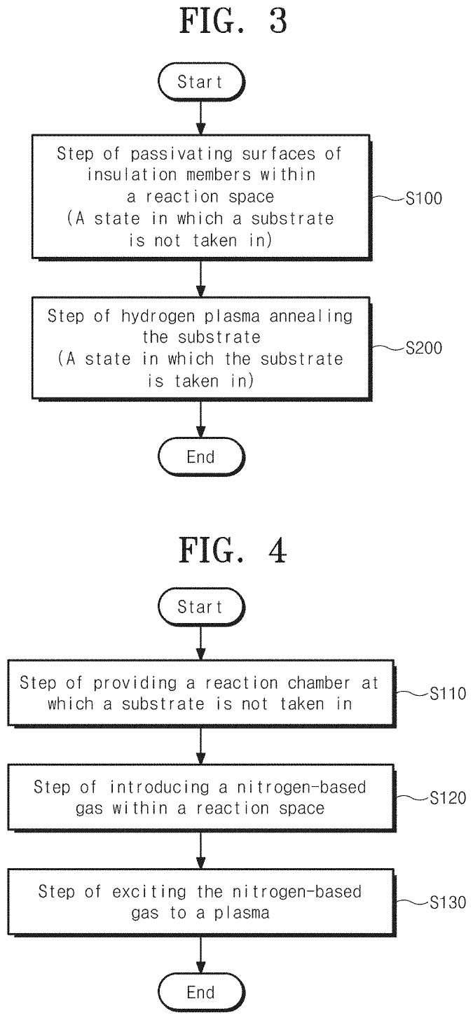

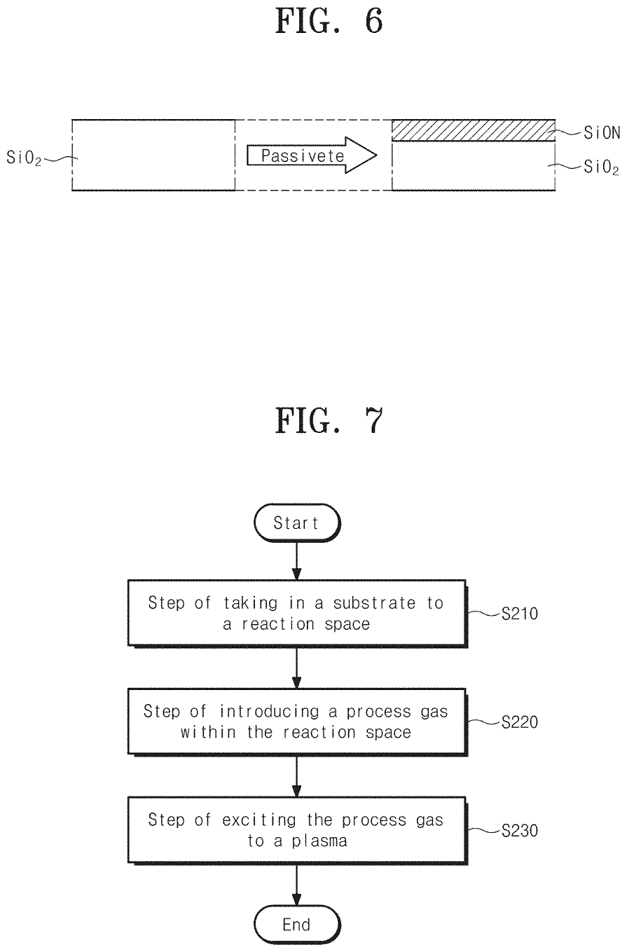

FIG. 3 is a flowchart showing a substrate treating method according to an embodiment of the inventive concept, FIG. 4 is a flowchart showing the substrate treating method according to step S100 of FIG. 3, and FIG. 6 schematically illustrates surfaces of insulation members being changed by a nitrogen passivation through step S100 of FIG. 3.

Referring to FIG. 3, the substrate treating method in accordance with an embodiment of the inventive concept contains a passivation step S100 and a plasma annealing step S200. The passivation step S100 and the plasma annealing step S200 are sequentially performed. The plasma annealing step S200 is performed after the passivation step S100. The passivation step S100 and the plasma annealing step S200 may be repeated for multiple times. Prior to the hydrogen plasma annealing step S200, a corresponding passivation step S100 is performed once. The number of times the passivation step S100 is performed may be the same as the number of times the hydrogen plasma annealing (plasma annealing step) S200 is performed.

A substrate W to be treated which is carried into a reaction space may be provided as a material containing a silicon (Si). The substrate W may include a semiconductor substrate. However, the inventive concept is not limited thereto, and an object to be treated which is treated by a plasma treatment may include any one of a semiconductor substrate, a sapphire substrate, a glass substrate, an organic EL substrate, or a substrate for a flat panel display (FPD).

In the passivation step S100, surfaces of insulation members within the reaction space 101 may be passivated. The insulation members may be, for example, a dome member 490, a sidewall liner (not shown), an exhaust baffle (not shown), and the like provided as a ceiling of the reaction space 101. At least one of these components may be made of a material such as a quartz, an Al2O3, an AlN, and/or a Y2O3.

Referring to FIG. 4, the passivation step S100 is performed in a state in which the substrate W is not carried into the reaction space 101 (step S110). The substrate W may have been carried out to an outside before being taken in or after the hydrogen plasma annealing treatment has been completed in a previous step. In a state in which the substrate W is not taken into the reaction space 101, a nitrogen-based gas is supplied to the reaction space 101 as an embodiment of a passivation gas (step S120). The nitrogen-based gas may be supplied to the reaction space 101 through the first gas supply line 310 or the second gas supply line 320. Here, it is described that the nitrogen-based gas is supplied to the reaction space 101 through the second gas supply line 320. A controller 500 controls an opening/closing member 311 installed at the first gas supply line 310 to maintain a closed state while the nitrogen-based gas 101 is supplied to the reaction space 101, and controls the opening/closing member 321 installed at the second gas supply line 320 to maintain an open state.

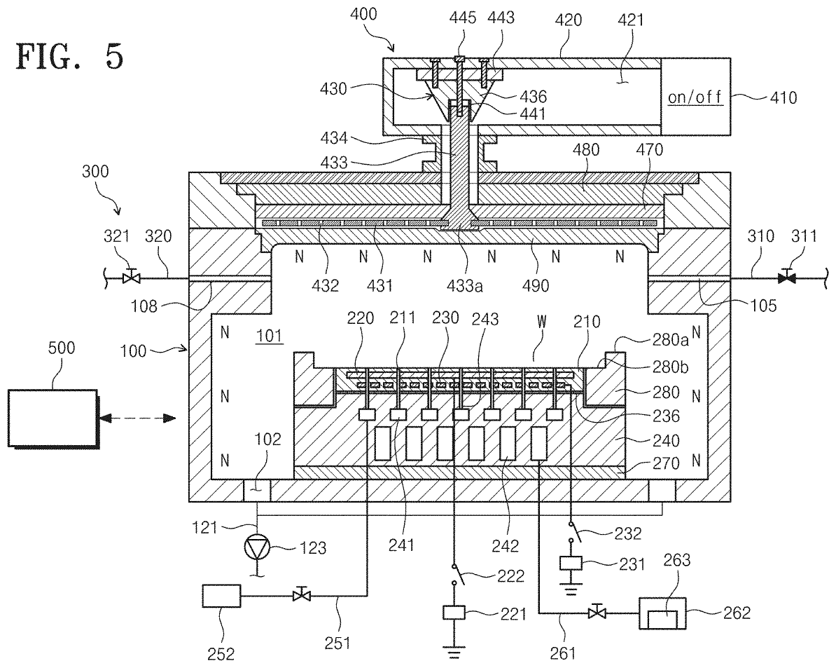

The nitrogen-based gas may be, for example, an N2, an ammonia (NH₃), a hydrazine (N2H4), a plasma N₂, a remote plasma N₂, or a combination of them. The nitrogen-based gas can be supplied for 10 seconds to 60 seconds at a flow rate of 10 sccm to 1000 sccm in a pressure atmosphere of 150 mTorr to 1000 mTorr. When the nitrogen-based gas is sufficiently supplied to the reaction space 101, a supply of the nitrogen-based gas is stopped. When the nitrogen-based gas is supplied to the reaction space 101, a hydrogen gas or an inert gas may be supplied together with the nitrogen-based gas. The hydrogen gas or the inert gas may be supplied to the reaction space 101 through the first gas supply line 310 or the second gas supply line 320. The hydrogen gas or the inert gas may be supplied to the reaction space 101 through a gas supply pipe different from the nitrogen-based gas. That is, the nitrogen-based gas may be supplied to the reaction space 101 through the second gas supply line 320, and the hydrogen gas or the inert gas may be supplied to the reaction space 101 through the first gas supply line 310. In this case, the controller 500 may control the opening/closing member 311 at the first gas supply line 310 and the opening/closing member 321 at the second gas supply line 320 to maintain an open state (see FIG. 5). In another embodiment, the hydrogen gas or the inert gas may be supplied to the reaction space 101 through a same gas supply pipe as the nitrogen-based gas. The hydrogen gas or the inert gas may be supplied at a flow rate of 10 to 1000 sccm while maintaining a pressure atmosphere of 150 mTorr to 1000 mTorr. The inert gas may include, for example, at least one of a helium (He), a neon (Ne), and/or an argon (Ar). When the hydrogen gas is supplied together at a supply stage S120 of the nitrogen-based gas, an effective nitrogen passivation is possible since the nitrogen is dissociated well in hydrogen. While the nitrogen-based gas is introduced into the reaction space 101, a microwave power source 410 is controlled to an off state.

Referring back to FIG. 4, after the step of introducing the nitrogen-based gas into the reaction space 101 (step S110), the nitrogen-based gas is excited to a plasma using a microwave applying unit 400 to generate the plasma (step S120). In this case, the microwave power source 410 is controlled to an on state. As the microwave power source 410 is controlled to the on state, an introduced passivation gas is excited in a plasma state. The plasma excited from the passivation gas passivates the surfaces of the insulation members.

FIG. 5 illustrates an image of the substrate treating apparatus performing step S100 of FIG. 5. Referring to FIG. 5, the opening/closing member 321 of the second gas supply line 320 is opened to introduce the passivation gas into the reaction space 101. In this case, the microwave power source 410 is controlled to an on state. The microwave power source 410 is controlled to the on state, and the passivation gas is excited in the plasma state. The plasma excited from the passivation gas reacts with a surface of the insulation member to passivate the insulation member.

FIG. 6 is a view schematically showing that surfaces of insulation components change by a nitrogen passivation through step S100 of FIG. 3. Although FIG. 5 illustrates a case where a material is a quartz (SiO2), those skilled in the art will understand that the same may be applied to other insulating materials (e.g., Al2O3, AlN, and Y2O3).

Referring to FIG. 6, it may be seen that a portion of a surface of a quartz component is converted into a silicon oxynitride (SiON). That is, the SiON was not deposited as a new layer on the previous quartz surface, but the previous quartz surface was converted into the SiON with a preset thickness by the passivation. Here, a nitrogen (N) may be derived from the nitrogen-based gas used for passivation, and other elements, that is, a silicon (Si) and an oxygen (O), may be derived from the quartz.

Referring back to FIG. 3, after passing through the surfaces of the insulation members within the reaction space (step S100), a hydrogen plasma annealing (HPA) may be performed on the substrate (step S200). When the hydrogen plasma annealing is performed on a component having a SiON passivation layer on a surface thereof, a SiON may be converted into SiO2.

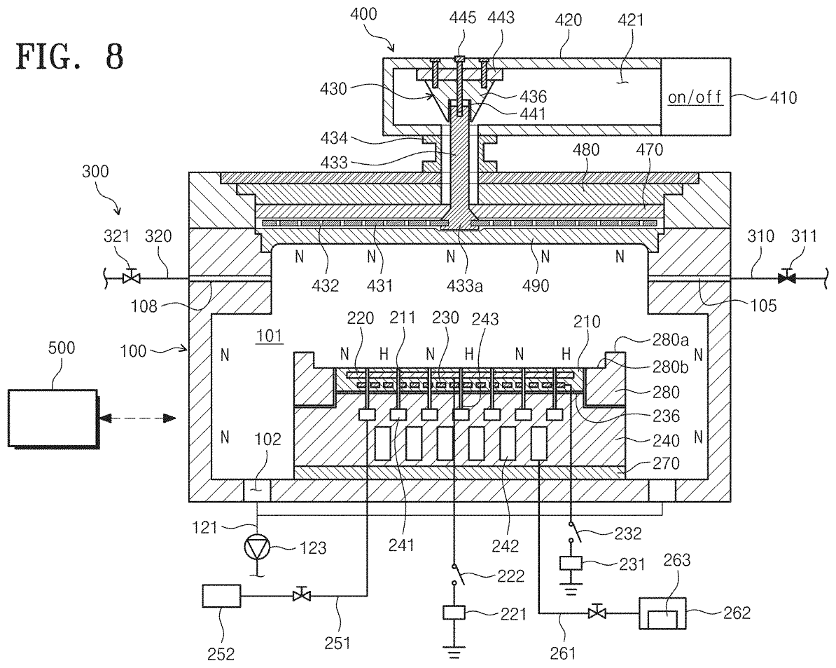

FIG. 7 is a flowchart showing a substrate treating method according to step S200 of FIG. 3, and FIG. 8 is a view illustrating a substrate treatment apparatus performing step S200 of FIG. 3.

Referring to FIG. 7, in an annealing step S200, a step of taking a substrate W into a reaction space 101 S210, a step of supplying a process gas into the reaction space 101 S220, and a step of exciting the process gas to a plasma S230 may be sequentially performed.

A substrate W taken into the reaction space 101 may be placed on a dielectric plate 210 of a substrate support member 200. When the substrate W is placed on the dielectric plate 210, a bottom power switch 222 is turned on to apply a DC current to a bottom electrode 220. An electric force is applied between the bottom electrode 220 and the substrate W by a current applied to the bottom electrode 220, and the substrate W is adsorbed to the dielectric plate 210 by the electric force. When the substrate W is adsorbed to the dielectric plate 210, the reaction space 101 is closed. Thereafter, the controller 500 operates a depressurizing member 123 to depressurize the reaction space 101 to a predetermined process pressure. For example, a process pressure may be 10 mTorr to 500 mTorr.

When the substrate W is adsorbed to the dielectric plate 210 and the reaction space 101 is depressurized to the process pressure, the process gas is supplied to the reaction space 101. Referring to FIG. 8, the controller 500 controls the opening/closing member 311 installed at the first gas supply line 310 to be maintained in an open state so the process gas is supplied to the reaction space 101, and controls the opening/closing member 321 installed at the second gas supply line 320 to be maintained in a closed state. The process gas may include a hydrogen (H₂) or an inert gas. For the process gas, only a hydrogen gas may be supplied, only an inert gas may be supplied, or both the hydrogen gas and the inert gas may be supplied.

After supplying the process gas to the reaction space 101, the process gas is excited into the plasma. The controller 500 controls the microwave power source 410 to an on state. An introduced process gas is excited to a plasma state, and the process gas is dissociated in the plasma as the microwave power source 410 is controlled to the on state. A surface of the substrate W may be plasma-treated by radicals generated at this time.

Although the above embodiment describes a plasma treatment using microwaves as an example, the inventive concept is not limited thereto, and the inventive concept may be applied to a plasma annealing treatment using a high frequency voltage. In addition, in the above embodiment, the inventive concept is applied to a plasma treatment for an annealing treatment, but is not limited thereto, and may be applied to a substrate treatment other than the annealing treatment, for example, a plasma treatment for an etching, a sputtering, and a film formation.

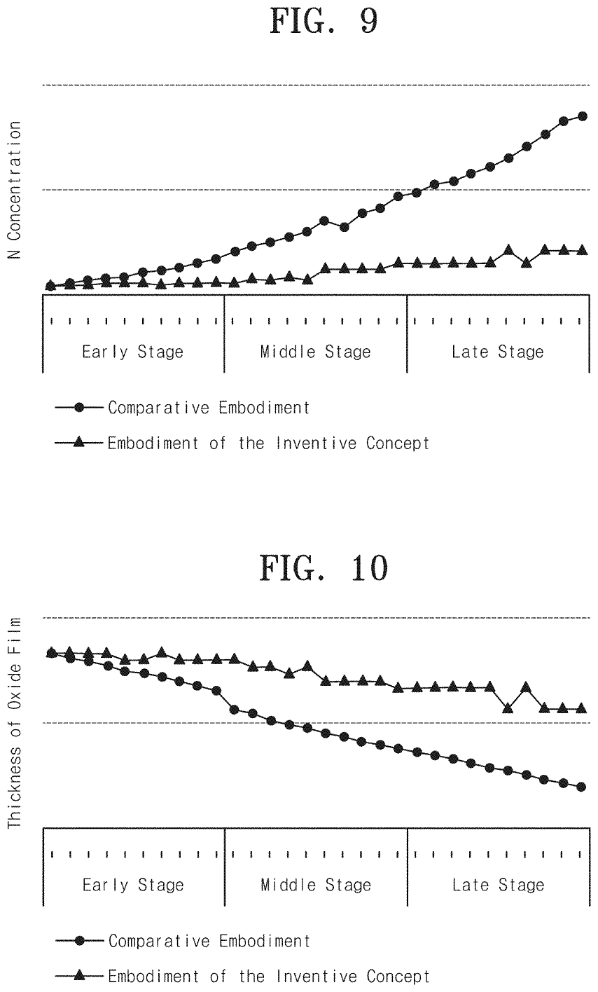

FIG. 9 is a graph comparing a change in an oxide film thickness of a substrate treating method according to an embodiment of the inventive concept and a substrate treating method according to a comparative embodiment, and FIG. 10 is a graph comparing a nitrogen concentration in a substrate according to an embodiment of the inventive concept.

According to the above-described description, a passivation step according to the present embodiment is performed in a pressure atmosphere in which a reaction space 101 of a process chamber 100 is in a range of 150 mTorr to 1000 mTorr. On the other hand, the passivation step according to a comparative embodiment of FIG. 9 and FIG. 10 is performed at a lower pressure than in the present embodiment. Specifically, a pressure in the passivation step according to the comparative embodiment may be 10 mTorr to 150 mTorr.

When the passivation gas is excited with a plasma in a state where the reaction space 101 of the process chamber 100 is maintained at a high pressure, a generated plasma may have a weak plasma property. In this case, the weak plasma property may mean a state in which a concentration of a passivation gas component contained in the plasma is low and a distance between the active particles contained in the plasma is relatively far. On the contrary, when the passivation gas is excited to the plasma in a state in which the reaction space 101 of the process chamber 100 is maintained at a low pressure, the generated plasma may have a strong plasma property. In this case, the strong plasma property may mean a state in which the concentration of the passivation gas component contained in the plasma is high and a distance between the active particles contained in the plasma is relatively close. Accordingly, in the case of the plasma generated in the passivation step according to the present embodiment, a plasma weaker than the plasma generated in the passivation step according to the comparative embodiment may be generated.

When the insulation member is passivated at the passivation step S100, a layer including a nitrogen component may be deposited on a surface of the insulation member. Thereafter, when the substrate W is taken in to perform a nitrogen plasma annealing step S200, a part of the nitrogen components deposited on the insulation member may react and be deposited on a surface of the substrate W.

In this case, in accordance with the comparative embodiment, relatively more nitrogen components remain in the reaction space 101 than in the present embodiment, thereby increasing the nitrogen component deposited on the substrate W. In general, a plurality of substrates W are continuously treated in one substrate treatment apparatus 10, and in this process, a concentration of a passivation component (nitrogen component) deposited on a first substrate to be treated first and a passivation component (nitrogen component) deposited on an Nth substrate to be treated last is different. As a continuous treatment is performed at one substrate treating apparatus 10, the passivation gas component (nitrogen component) remaining on a surface of the reaction space 101 or the insulation member of the reaction chamber 100 is increased, and thus the passivation gas component deposited on the Nth substrate is greater than the passivation gas component deposited on the first substrate. When the nitrogen concentration in the substrate W is not constant, a subsequent oxide film may not be constantly grown. That is, in a process of growing the subsequent oxide film, a difference in a thickness of the oxide film occurs, and accordingly, a performance of the device is degraded.

However, in accordance with this embodiment, a passivation is performed by generating a weak nitrogen plasma, and thus a nitrogen concentration in a process chamber 100 is relatively lower than that of a comparative embodiment. Therefore, when a plurality of substrates W are treated, a difference in the nitrogen concentration between the plurality of substrates W may be minimized or maintained constant. Accordingly, the subsequent oxide film may be uniformly grown.

A y-axis of FIG. 9 represents a nitrogen concentration in a reaction space, and an x-axis represents a classification of a use time when one substrate treating apparatus 10 is cumulatively used. Referring to FIG. 9, in accordance with a comparative embodiment, it can be seen that the nitrogen concentration increases from a beginning toward a second half as the substrate treatment apparatus 10 is cumulatively used. On the other hand, in accordance with this embodiment, it can be confirmed that the nitrogen concentration in the early, middle, and late stages is maintained constant despite the cumulative use of the substrate treatment apparatus 10.

A y-axis of FIG. 10 represents a thickness of an oxide film growing on a substrate W, and an x-axis represents a classification of a use time when one substrate treating apparatus 10 is cumulatively used. Referring to FIG. 10, in accordance with a comparative embodiment, as the substrate treating apparatus 10 is cumulatively used, the thickness of the oxide film decreases from a beginning toward a second half, and a thickness deviation between the first substrate and an Nth substrate increases. On the other hand, in accordance with this embodiment, it can be confirmed that the thickness of the oxide film of the substrate W maintains a constant thickness within an error range despite an accumulated use of the substrate treatment apparatus 10. That is, it may be seen that the thickness deviation between the first substrate and the Nth substrate is significantly smaller than that of the comparative embodiment.

Accordingly, the present embodiment may effectively perform a surface treatment of a substrate. In addition, the present embodiment protects insulation members provided to the apparatus and minimizes a particle contamination on the substrate. In addition, the present embodiment may maintain a constant nitrogen concentration in the substrate. In addition, the present embodiment may grow a film having a constant thickness.

In addition, in the above-described example, a plasma including hydrogen radicals is generated through microwaves, but the inventive concept is not limited thereto, and the above-described embodiment may be applied in the same or similar manner as long as the apparatus has a temperature control member for controlling a temperature of the substrate W and a plasma source for generating a plasma from a process gas.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1.-12. (canceled)

13. A substrate treating method comprising:
passivating an insulation member within a reaction space; and
hydrogen plasma annealing treating a substrate, and
wherein the passivating the insulation member within the reaction space includes:
providing a reaction chamber at which a substrate has not been introduced to the reaction space;
supplying a passivation gas into the reaction space; and
exciting the passivation gas to a plasma.

14. The substrate treating method of claim 13, wherein a pressure of the reaction space at the passivating the insulation member within the reaction space is a pressure of 150 mTorr to 1000 mTorr.

15. The substrate treating method of claim 14, wherein the passivation gas includes a nitrogen-based gas, and
the nitrogen-based gas is supplied at a flow rate of 10 sccm to 1000 sccm for 10 seconds to 60 seconds.

16. The substrate treating method of claim 15, wherein the passivation gas further includes a hydrogen gas or an inert has, and
the hydrogen gas or the inert gas is supplied at a flow rate of 10 sccm to 1000 sccm together with the nitrogen-based gas.

17. The substrate treating method of claim 13, wherein the hydrogen plasma annealing treating the substrate is performed after the passivating the insulation member within the reaction space.

18. The substrate treating method of claim 17, wherein the hydrogen plasma annealing treating the substrate comprises:
taking in the substrate to the reaction space;
supplying a process gas within the reaction space; and
exciting the process gas to the plasma.

19. The substrate treating method of claim 18, wherein the process gas is a hydrogen gas or an inert gas.

20. (canceled)
